(19) United States
(12) Patent Application Publication
(10) Pub. No.: US 2011/0298445 A1
(43) Pub. Date: Dec. 8, 2011

(54) MULTIPOINT SENSOR

(75) Inventors: Pascal Joguet, Sadirac (FR); Julien Olivier, Bordeaux (FR)

(73) Assignee: STANTUM, BORDEAUX (FR)

(21) Appl. No.: 13/201,548

(22) PCT Filed: Feb. 17, 2010
(86) PCT No.: PCT/FR10/00135

§ 371 Date: Aug. 15, 2011

(30) Foreign Application Priority Data
Feb. 17, 2009 (FR) 0900715

(51) Int. Cl. G01R 19/00

(52) U.S. Cl. 324/76.11

(57) ABSTRACT

The invention relates to a multipoint sensor (1), including: an upper layer (3) made of conducting tracks arranged in lines; a lower layer (6) made of conducting tracks arranged in columns; spacers (4) provided between the upper layer and the lower layer so as to insulate the upper layer (3) and the lower layer (6), characterised in that the sensor further includes at least one resistive intermediate layer (5) provided between the spacers and at least one layer from among the upper conducting layer and the lower conducting layer.

The invention relates a multipoint sensor.

Such a sensor is described for example in the application EP 1719047 which teaches a multipoint sensor comprising:
an upper layer constituted by conductive tracks organized in rows;
a lower layer constituted by conductive tracks organized in columns;
spacers positioned between the upper layer and the lower layer so as to insulate the upper layer from the lower layer.

Such a sensor may in particular enable the detection of several activation zones at the same time thanks to sequential scanning of the conductive rows and columns as described in the aforementioned application EP1719047.

When a user presses on such a sensor, the upper layer comes into contact with the lower layer in the parts situated between the spacers. Since the upper layer and the lower layer are conductive, this contact enables the position of the points of contact to be located.

The upper layer is for example constituted by rows of ITO (indium tin oxide), which is a translucent conductive material. This layer is positioned for example under a layer of PET (polyethylene terephthalate). The lower layer is for example constituted by columns of ITO (indium tin oxide), positioned for example above a layer of glass.

When the user presses on the sensor, the rows of ITO enter directly into contact with the columns of ITO between the spacers.

However, as ITO has a non-negligible resistance along the rows and the columns, but a much lower vertical resistance at the locations of contact between the two layers; when several points of contact are activated, in particular orthogonally on the rows and the columns, the electrical characteristics appearing at the intersection of a row and a column are perturbed by the other contact points situated on those same rows and columns.

For example, when the user presses with three fingers placed orthogonally on the upper layer, the transmission of the signal between the rows, the columns and the contact points gives approximately the same measurements as if a fourth finger was placed in that same orthogonality. Similarly, problems of masking may hinder the satisfactory detection of the position of the fingers. Lastly, this particularity makes the exact detection of the contact zones difficult or even impossible, since the orthogonalities tend to limit the detection to rectangular zones, even in case of contact zones having diagonals.

In the state of the art, these problems may be resolved by virtue of electronic processing and different correction algorithms.

An object of the invention is to reduce the problems of masking and orthogonality between the contact points on the sensor without necessarily using electronic processing.

This problem is solved according to the invention by a multipoint sensor as described previously, further comprising at least one resistive intermediate layer positioned between the spacers and at least one of the conductive upper layer and the conductive lower layer.

By virtue of this resistive additional layer, when a user presses on the sensor, the conductive upper layer is not directly in contact with the conductive lower layer. The presence of this resistive material between the two conductive layers then enables the problems of orthogonality and masking to be reduced. In use, in particular when the conductive upper layer is pressed on, between the spacers, the conductive upper layer is in contact with the resistive intermediate layer, which is itself in contact with the conductive lower layer. Detection of one or more contact points is then possible.

At least one of the upper or lower layers is preferably transparent and, according to a preferred embodiment, the multipoint sensor is formed of transparent layers, so as to be transparent.

Preferably, the layer of resistive material is configured so as to obtain quite a high vertical resistance between the lower and upper conductive layers, while maintaining a satisfactory quantity of signal.

In particular, the lower layer has a linear resistance, the upper layer has a linear resistance, and the vertical resistance of the intermediate layer is greater than the linear resistance of the lower layer and the linear resistance of the upper layer.

Preferably, the vertical resistance of the intermediate layer is at least one hundred times greater than the linear resistance of the lower layer and of the upper layer.

For example, the vertical resistance, that is to say in a direction perpendicular to the plane of the upper layer and of the lower layer and over the section corresponding to the intersection of a row and of a column, has a value ranging from 50 kiloOhms to 200 kiloOhms.

This range of values is in particular preferred when the rows of the upper layer and the columns of the lower layer form a matrix of square cells, for example having sides of 1.5 millimeters, and the ratio of the linear resistance of the ITO to the width of the conductive tracks is between 100 and 500 Ohms. The intermediate layer advantageously has a much higher impedance than the impedance of the conductive material of the upper and lower layers.

The intermediate layer is preferably transparent and is for example of silicone.

Other advantageous features of the invention are described below with reference to the appended drawings in which:

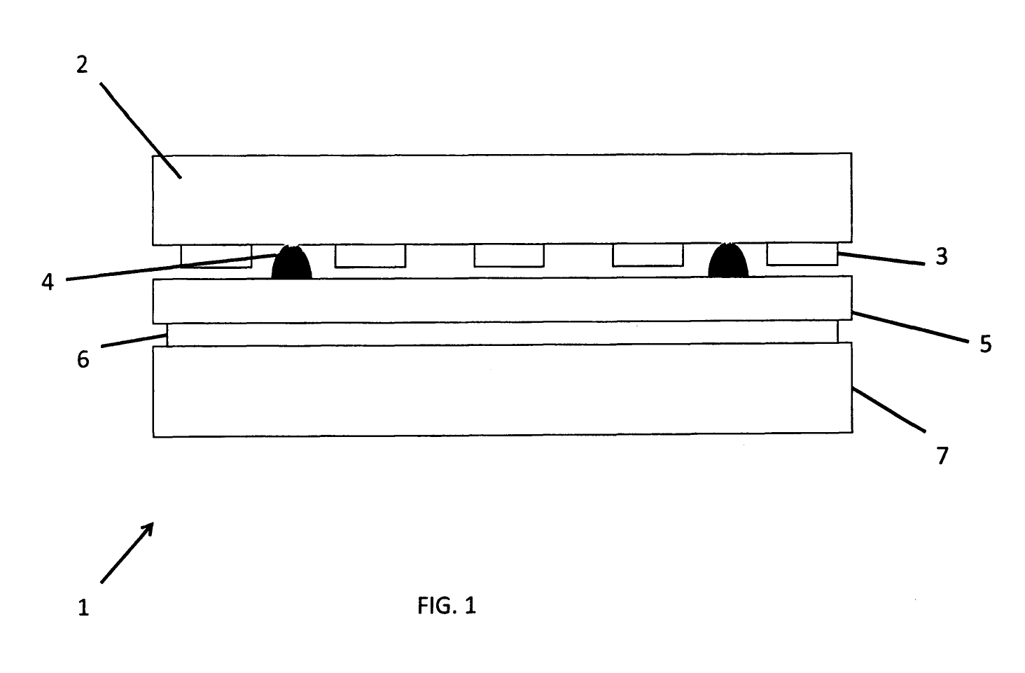

FIG. 1 shows a cross-section view of a multipoint sensor according to a first embodiment of the invention;

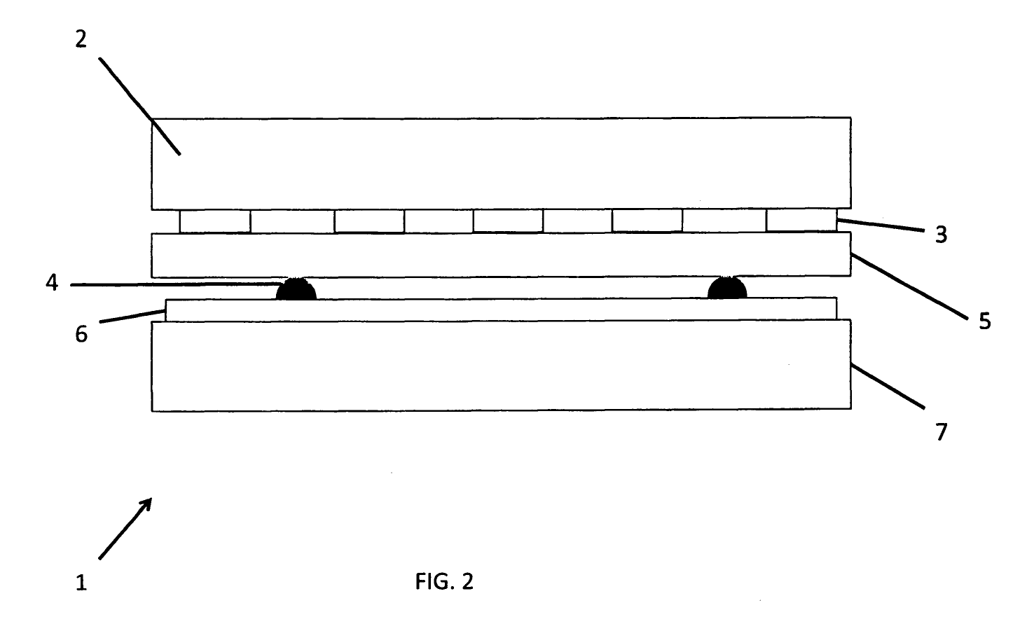

FIG. 2 shows a cross-section view of a multipoint sensor according to a second embodiment of the invention;

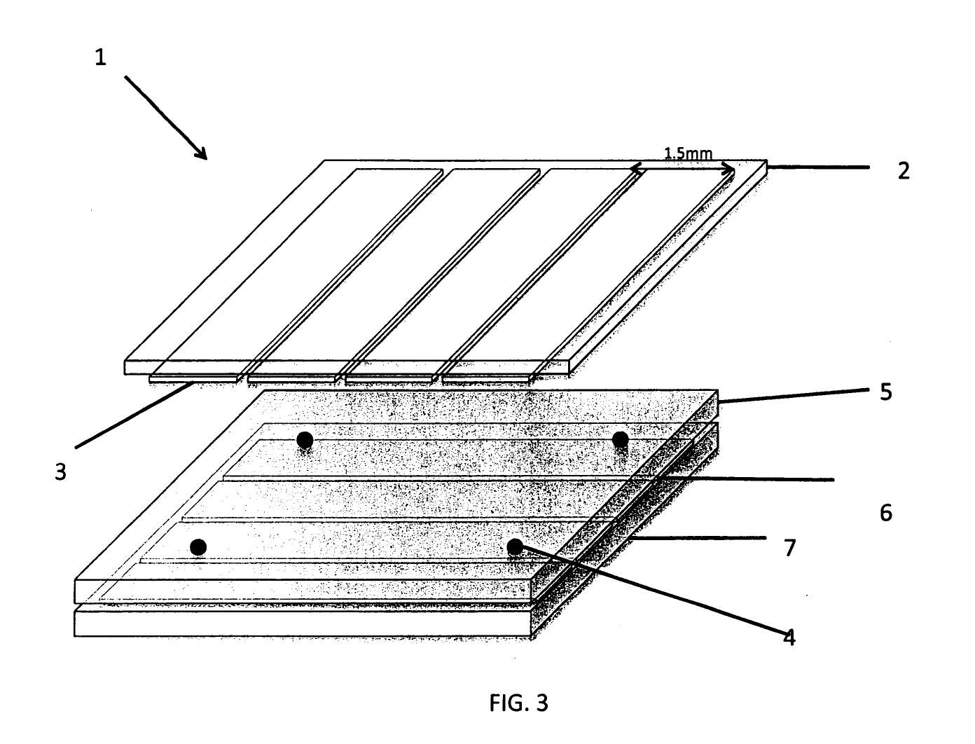

FIG. 3 shows an exploded view of a multipoint sensor according to the invention.

In the Figures, identical references relate to similar technical parts.

A multipoint sensor 1 according to the invention is shown in FIG. 1.

Preferably, this multipoint sensor 1 is a transparent multipoint sensor such that the different layers constituting that sensor are transparent.

In what follows, a transparent sensor 1 will be described but it is to be understood that the invention is also applicable to a non-transparent sensor 1 thus comprising at least one non-transparent layer.

In FIG. 1, the sensor 1 comprises, in its upper part, a layer of PET (polyethylene terephthalate) 2. Under this layer of PET 2, there is an upper layer 3 of ITO (indium tin oxide), which is a translucent conductive material. The layer 3 of ITO forms structuring for the layer 2 of PET and corresponds to the rows of the sensor 1.

The sensor 1 further comprises a layer of glass 7 in its lower part. Above this layer is a lower layer 6 of ITO. The layer 6 of ITO forms structuring for the glass layer 7 and corresponds to the columns of the sensor 1.

It is understood that the concepts of rows and columns are relative concepts and may be interchanged according to the orientation of the sensor. Uniquely by convention, it will be considered that the upper layer 3 of ITO forms the rows of a matrix sensor, but it is clear for the person skilled in the art that it could also form the columns thereof. In that case, the lower layer 6 of ITO would form the rows of that matrix sensor. In both cases, the direction of the tracks of ITO forming the upper layer is perpendicular to the direction

According to the embodiment illustrated in FIG. 1, an intermediate layer 5 has been positioned above the lower layer 6 of ITO. Above that intermediate layer 5 are located spacers 4 arranged such that, when the upper layer of PET 2 is not pressed on, the layer 3 of ITO is not in contact with the intermediate layer 5.

When the sensor 1 is not pressed, the upper layer 3 of ITO is thus insulated from the lower layer 6 of ITO by virtue of the spacers 4.

The layers of ITO, of PET and of glass are transparent, such that the sensor is transparent in this case.

FIG. 2 shows another embodiment of the invention in which, instead of being positioned between the lower layer 6 of ITO and the spacers 4, the intermediate layer 5 is positioned between the upper 3 layer of ITO and the spacers 4.

The embodiments of FIGS. 1 and 2 may possibly be combined according to the invention. In this case, two distinct intermediate layers such as the intermediate layer 5 may be used. The first intermediate layer may then be positioned between the upper layer 3 of ITO and the spacers 4 as in FIG. 2, and the second intermediate layer be positioned between the lower layer of FIG. 6 and the spacers 4.

FIG. 3 shows an exploded perspective view of the embodiment of FIG. 1. In this FIG. 3, there are thus shown the upper layer 2 of PET, the upper rows 3 of ITO, the spacers 4, the intermediate layer 5, the lower columns 6, and the lower layer 7 of glass.

The upper rows 3 of ITO may have a width of 1.5 millimeters. In the same way, the lower columns of ITO may have a width of 1.5 millimeters. The rows 3 of ITO and the columns 6 of ITO thus form a matrix of square cells with sides of 1.5 millimeters.

The multipoint sensor 1 described above is adapted to be positioned above a screen enabling different objects to be displayed, such that the aforementioned different layers are preferably transparent.

ITO has in particular the advantage of being a material that is conductive and transparent.

The intermediate layer 5 is now described in more detail as it is used in the embodiments of FIGS. 1 to 3 described above.

The intermediate layer 5 is transparent with a low electrical conductivity. It forms a continuous unstructured layer. A maximum transmittance is sought in order not to affect the optical performance of the sensor.

The intermediate layer 5 has a very low conductivity.

Preferably, it has a vertical resistance, that is to say in a direction perpendicular to the plane of the upper layer 3 of ITO and of the lower layer 6 of ITO, comprised between 50 kiloOhms and 200 kiloOhms in the square cell with sides of 1.5 millimeters described above.

The vertical resistance value is chosen so as to be at least one hundred times greater than the linear resistance of the layers of ITO, which makes it possible to avoid the problems of masking of points satisfactorily, on use of the sensor.

The vertical resistance value is furthermore chosen so as to maintain a satisfactory signal level in use, that is to say when the upper layer 3 of ITO is in contact with the resistive intermediate layer 5, which is itself in contact with the lower layer 6 of ITO.

The Applicant has determined, through tests, that the range from 50 kiloOhms to 200 kiloOhms in the square cell with sides of 1.5 millimeters described above provides a good compromise between the signal level and the improvement in relation to the masking problems.

The intermediate layer 5 is for example formed of a semiconductor material, in particular silicone. The thickness of the layer is then for example of the order of 300 micrometers, for a resistivity of 6400hm·m.

In this case, for a 1.5 millimeter square cell as described earlier, the vertical resistance of the silicone layer is 85.4 kiloOhms. This value is then clearly within the aforementioned range.

In use, a user presses on the upper layer of PET 2, and possibly with several fingers at the same time, the effect of which is that, in the two embodiments described earlier, the upper layer 3 of ITO is in contact with the intermediate layer 5, which is itself in contact with the lower layer 6 of ITO. Detection of the contact of the user's finger or fingers is then possible.

Preferably, sequential scanning of the matrix formed by the rows and the columns of ITO may be carried out. This scanning is for example as described in the application EP 1719047.

1. A multipoint sensor (1) comprising:
an upper layer (3) constituted by conductive tracks organized in rows;
a lower layer (6) constituted by conductive tracks organized in columns;
spacers (4) positioned between the upper layer and the lower layer so as to insulate the upper layer (3) and the lower layer;
the sensor further comprises at least one resistive intermediate layer (5) positioned between the spacers and at least one of the conductive upper layer and the conductive lower layer; characterized in that the lower layer (6) has a linear resistance, and the upper layer (3) has a linear resistance, and the intermediate layer (5) has a vertical resistance and the vertical resistance of the intermediate layer (5) is greater than the linear resistance of the lower layer (6) and the linear resistance of the upper layer (3).

2. A multipoint sensor according to claim 1 in which at least one of the upper or lower layers is transparent.

3. A multipoint sensor according to claim 2 in which the multipoint sensor is formed of transparent layers, so as to be transparent.

4. A multipoint sensor according to one of the preceding claims in which the vertical resistance of the intermediate layer (5) is a hundred times greater than the vertical resistance of the lower layer and of the upper layer.

5. A multipoint sensor according to one of the preceding claims in which The rows of the conductive upper layer (3) and the columns of the conductive lower layer (6) form a matrix of square cells.

6. A multipoint sensor according to the preceding claim in which the square cells have sides of 1.5 millimeters.

7. A multipoint sensor according to one of the preceding claims in which the vertical resistance of the intermediate layer (5) has a value ranging from 50 kiloOhms to 200 kiloOhms.

8. A multipoint sensor according to one of the preceding claims in which the intermediate layer (5) is of silicone.

9. A multipoint sensor according to one of the preceding claims in which the upper layer is constituted by rows of indium tin oxide ITO.

10. A multipoint sensor according to one of the preceding claims in which the lower layer is constituted by columns of indium tin oxide ITO.

11. A multipoint sensor according to one of the preceding claims in which the conductive upper layer is situated under a layer (2) of polyethylene terephthalate PET.

12. A multipoint sensor according to one of the preceding claims in which the conductive lower layer is situated above a layer of glass (7).

13. A multipoint sensor according to one of the preceding claims in which the intermediate layer is transparent.

14. A multipoint sensor according to one of the preceding claims in which the intermediate layer has a much higher impedance than the impedance of the conductive material of the upper and lower layers.
